(19) United States
(12) Patent Application Publication
(10) Pub. No.: US 2025/0324180 A1
(43) Pub. Date: Oct. 16, 2025

(54) PHOTOELECTRIC CONVERSION APPARATUS AND EQUIPMENT

(71) Applicant: CANON KABUSHIKI KAISHA, Tokyo (JP)

(72) Inventors: TATSUYA RYOKI, Kanagawa (JP); KOHICHI NAKAMURA, Kanagawa (JP)

(21) Appl. No.: 19/173,442

(22) Filed: Apr. 8, 2025

(30) Foreign Application Priority Data
Apr. 15, 2024 (JP) 2024-065498

(51) Int. Cl. H04N 25/79; H04N 25/778; H04N 25/78; H10F 39/00

(52) U.S. Cl. CPC H04N 25/79; H04N 25/778; H04N 25/78; H10F 39/809

(57) ABSTRACT

A photoelectric conversion apparatus includes a first substrate having a pixel array, a second substrate having a memory array configured to retain an analog signal output by the pixel array, and a third substrate having an analog-to-digital conversion circuit configured to convert the analog signal output by the memory array into a digital signal. The second substrate has at least one memory control circuit configured to control the memory array, and the first substrate or the third substrate has at least one pixel control circuit configured to control the pixel array.

### BACKGROUND

### Field of the Disclosure

The present disclosure relates to a photoelectric conversion apparatus and equipment.

### Description of the Related Art

Japanese Patent Laid-Open No. 2022-51548 proposes an image sensor equipped with a so-called global shutter function, which has a charge retaining section that temporarily retains the signal charge, and which enables simultaneous transfer of the signal charge from a photoelectric conversion section to the charge retaining section across multiple pixels. By using the global shutter function, the timing of signal accumulation in the photoelectric conversion section can be synchronized across multiple pixels, thereby suppressing distortion in images of a fast-moving object when capturing images of the object.

However, in the image sensor with the global shutter function disclosed in Japanese Patent Laid-Open No. 2022-51548, driving multiple pixels at the same time affects the operation of other circuits operating with the same timing, and this is not taken into consideration in Japanese Patent Laid-Open No. 2022-51548.

### SUMMARY

The present disclosure provides a photoelectric conversion apparatus having higher performance.

According to embodiments of the present disclosure, there is provided a photoelectric conversion apparatus including a first substrate having a pixel array, a second substrate having a memory array configured to retain an analog signal output by the pixel array, and a third substrate having an analog-to-digital conversion circuit configured to convert the analog signal output by the memory array into a digital signal. The second substrate has at least one memory control circuit configured to control the memory array, and the first substrate or the third substrate has at least one pixel control circuit configured to control the pixel array.

Further features of the present disclosure will become apparent from the following description of exemplary embodiments with reference to the attached drawings.

### BRIEF DESCRIPTION OF THE DRAWINGS

FIG. 1 is a schematic diagram illustrating a photoelectric conversion apparatus according to a first embodiment.

FIG. 2 is a block diagram illustrating the photoelectric conversion apparatus according to the first embodiment.

FIG. 3 is a block diagram illustrating the photoelectric conversion apparatus according to the first embodiment.

FIG. 4 is a block diagram illustrating the photoelectric conversion apparatus according to the first embodiment.

FIG. 5 is a circuit diagram illustrating the photoelectric conversion apparatus according to the first embodiment.

FIG. 6 is a driving timing chart illustrating the photoelectric conversion apparatus according to the first embodiment.

FIG. 7 is a block diagram illustrating a photoelectric conversion apparatus according to a first modification of the first embodiment.

FIG. 8 is a block diagram illustrating a photoelectric conversion apparatus according to a second modification of a third embodiment.

FIG. 9 is a circuit diagram illustrating a photoelectric conversion apparatus according to a second embodiment.

FIG. 10 is a driving timing chart illustrating the photoelectric conversion apparatus according to the second embodiment.

FIG. 11 is a block diagram illustrating a photoelectric conversion apparatus according to a third embodiment.

FIGS. 12A, 12B, and 12C are schematic diagrams each illustrating equipment according to a fourth embodiment.

### DESCRIPTION OF THE EMBODIMENTS

Embodiments will now be described with reference to the drawings. Note that the following embodiments are not intended to limit the disclosure. Multiple features are described in the embodiments, but not all of these features are necessarily essential to embodiments of the disclosure, and multiple such features may be combined as appropriate. Furthermore, in the attached drawings, the same reference numerals are given to the same or similar configurations, and redundant description thereof is omitted. Additionally, in each of the embodiments described below, a sensor for imaging is mainly described as an example of a photoelectric conversion apparatus. However, each embodiment is not limited to sensors for imaging and is applicable to other examples of photoelectric conversion apparatuses. For example, such examples include imaging apparatuses, distance measuring apparatuses (such as those using focal detection or Time of Flight (TOF) for distance measurement), and photometric apparatuses (such as those for measuring the amount of incident light).

In this specification, terms indicating specific directions or positions (e.g., “up,” “down,” “right,” “left,” and other terms incorporating these) may be used as necessary. The use of such terms is intended to facilitate understanding of the embodiments with reference to the drawings and does not limit the technical scope of the present disclosure based on the meaning of these terms.

In this specification, when it is stated that “member A and member B are electrically connected,” it does not necessarily mean that member A and member B are directly connected. For example, even if another member C is connected between member A and member B, they are considered connected as long as there is an electrical connection.

In this specification, the term “plane” refers to a surface in a direction parallel to the main surface of a substrate. The main surface of a substrate may include the light-incident surface of a substrate including a photoelectric conversion element, a surface on which multiple analog-to-digital converters (ADCs) are disposed repeatedly, or the bonding surface between substrates in a multilayer photoelectric conversion apparatus. In addition, the term “plan view” refers to a view as seen from a direction perpendicular to the main surface of a substrate. Furthermore, the term “cross-section” refers to a surface in a direction perpendicular to the light-incident surface of a semiconductor layer. Additionally, the term “cross-sectional view” refers to a view as seen from a direction parallel to the main surface of a substrate.

Wiring, pads, and other metal components described in this specification may be composed of a single metal element or a mixture (alloy). For example, wiring described as copper wiring may be composed solely of pure copper or may primarily include copper with additional components. Similarly, a pad connected to an external terminal may be composed solely of pure aluminum or may primarily include aluminum with additional components. The copper wiring and aluminum pads mentioned here are merely examples and can be changed to various other metals. Furthermore, the wiring and pads described here are examples of metal components used in the photoelectric conversion apparatus, and they may also be applied to other metal components.

### First Embodiment

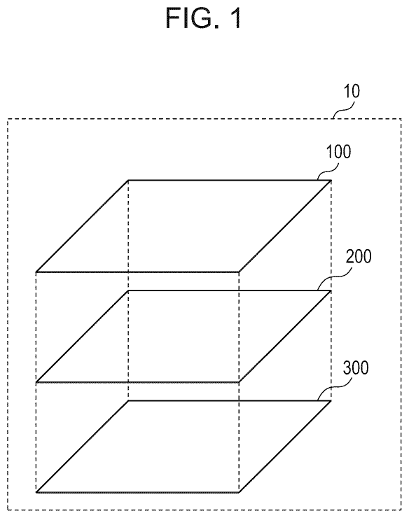

A photoelectric conversion apparatus according to a first embodiment of the present disclosure will be described using FIGS. 1 to 6.

FIG. 1 is an example of a schematic diagram of a photoelectric conversion apparatus according to the present embodiment.

As illustrated in FIG. 1, a photoelectric conversion apparatus 10 includes three substrates: a first substrate 100, a second substrate 200, and a third substrate 300. The photoelectric conversion apparatus 10 has a three-dimensional structure composed of these three substrates laminated together. Also, the first substrate 100, the second substrate 200, and the third substrate 300 are laminated in this order.

Note that the first substrate 100, the second substrate 200, and the third substrate 300 may each be a semiconductor substrate such as a silicon substrate. Note that the sizes of the first substrate 100, the second substrate 200, and the third substrate 300 may be substantially equal. The relationship of being “substantially equal” as used here will be described. The term “substantially equal” refers to a relationship that is designed to be equal but may have slight differences due to manufacturing tolerances. The term “substantially equal” encompasses these minor differences resulting from manufacturing errors.

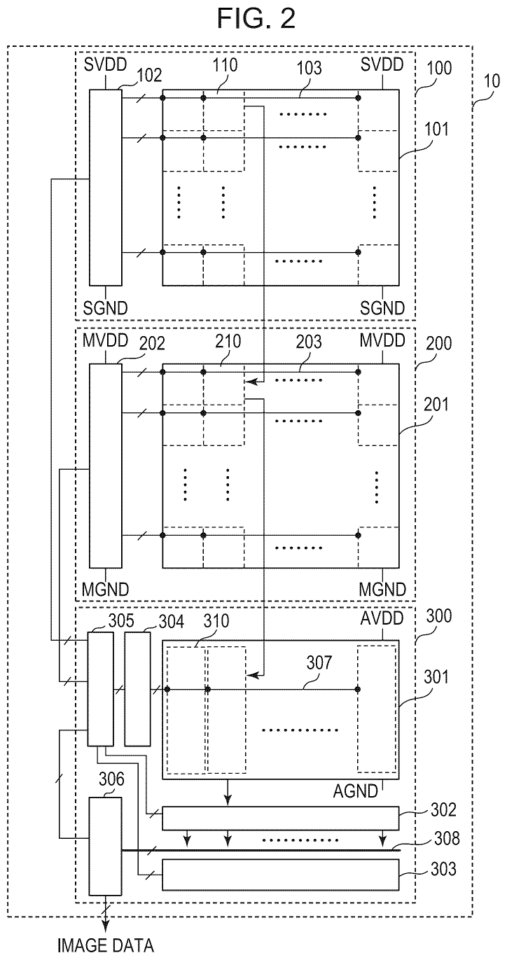

FIG. 2 is an example of a block diagram of the photoelectric conversion apparatus according to the present embodiment.

As illustrated in FIG. 2, the first substrate 100 has a pixel array 101, a pixel control circuit 102, and control lines 103. The pixel array 101 has multiple pixels 110 performing photoelectric conversion, and these pixels 110 are provided across multiple rows and multiple columns within the pixel array 101. Each of the pixels 110 includes a photoelectric conversion element configured to generate and accumulate the signal charge in response to the amount of light received, and output a pixel signal in response to the amount of incident light. Note that the pixel signal output from each pixel 110 is an analog signal.

Note that, in this specification, the horizontal direction in the drawings is referred to as the row direction, and the vertical direction as the column direction. The number of rows and columns of the pixels 110 disposed in the pixel array 101 is not particularly limited. The pixels 110 may include not only effective pixels that output pixel signals in response to the amount of incident light but also optical black pixels with photoelectric conversion elements shielded from light or dummy pixels that do not output signals.

Additionally, in the rows of the pixel array 101, multiple control lines 103 extending in the row direction are disposed. Each of these control lines 103 is connected to multiple pixels 110 aligned in the row direction. A single control line 103 commonly controls multiple pixels 110 disposed in each row. The pixel control circuit 102 supplies control signals to the individual pixels 110 via the control lines 103. The pixel array 101 and the pixel control circuit 102 are supplied with a voltage SVDD, which is a power supply voltage, and a voltage SGND, which is a reference voltage.

The second substrate 200 has a memory array 201, a memory control circuit 202, and control lines 203. The memory array 201 has multiple memory circuits 210 retaining pixel signals output from multiple pixels 110, and these memory circuits 210 are provided across multiple rows and multiple columns within the memory array 201. Note that a pixel signal output from a pixel 110 disposed in a specific row and column may be retained by a memory circuit 210 disposed in the same row and column as the row and column where the pixel 110 is disposed.

Additionally, in the rows of the memory array 201, multiple control lines 203 extending in the row direction are disposed. Each of these control lines 203 is connected to multiple memory circuits 210 aligned in the row direction. A single control line 203 commonly controls multiple memory circuits 210 disposed in each row. The memory control circuit 202 supplies control signals to the individual memory circuits 210 via the control lines 203. The memory array 201 and the memory control circuit 202 are supplied with a voltage MVDD, which is a power supply voltage, and a voltage MGND, which is a reference voltage.

The third substrate 300 has a signal processing circuit 301, a column memory circuit 302, a horizontal scanning circuit 303, a column circuit control circuit 304, a timing control circuit 305, an output circuit 306, a control line 307, and a horizontal output line 308. The signal processing circuit 301 includes column circuits 310 corresponding to the individual pixel columns. Each of the column circuits 310 performs predetermined processing, such as amplification processing, analog-to-digital (AD) conversion processing, or the like, on pixel signals read from the memory circuits 210 disposed in the corresponding column. Note that the AD conversion method can be of various types, such as slope-type AD conversion, successive approximation AD conversion, or 42 (delta-sigma) AD conversion.

Additionally, the signal processing circuit 301 is provided with the control line 307 extending in the row direction. The control line 307 is connected to the column circuits 310 disposed in the row direction. The control line 307 commonly controls these column circuits 310. The column circuit control circuit 304 supplies a control signal to each column circuit 310 via the control line 307. The column memory circuit 302 retains the pixel signal having gone through the signal processing performed by each column circuit 310.

The horizontal scanning circuit 303 includes logic circuits such as a shift register and an address decoder.

The horizontal scanning circuit 303 generates a control signal for reading pixel signals from the column memory circuit 302 and supplies the control signal to the column memory circuit 302. The horizontal scanning circuit 303 sequentially scans the column memory circuit 302 and inputs the pixel signals retained in the column memory circuit 302 to the output circuit 306 via the horizontal output line 308. The timing control circuit 305 supplies control signals to the pixel control circuit 102, the memory control circuit 202, the column memory circuit 302, the horizontal scanning circuit 303, the column circuit control circuit 304, and the output circuit 306. The signal processing circuit 301 is supplied with a voltage AVDD, which is a power supply voltage, and a voltage AGND, which is a reference voltage.

The output circuit 306, including a buffer amplifier, a differential amplifier, and the like, performs predetermined signal processing on pixel signals output from the pixels 110 in a column selected by the horizontal scanning circuit 303, and outputs the processed image data. Signal processing performed by the output circuit 306 includes, for example, correction processing through correlated double sampling (CDS), amplification processing, and the like. The output circuit 306 also includes a low voltage differential signal (LVDS)-type serial output circuit, which outputs the signal-processed digital signals to the outside of the photoelectric conversion apparatus at high speed and with low power consumption. Note that the output method is not limited to LVDS, and other methods may be used.

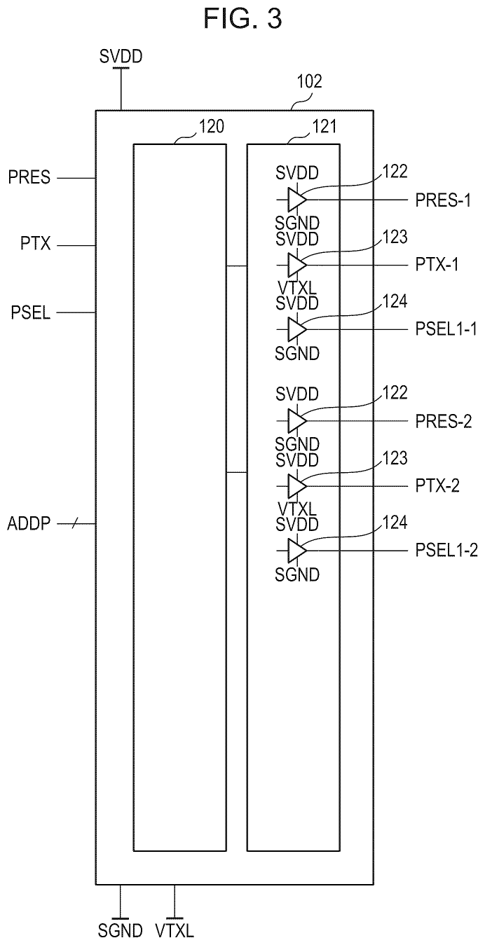

FIG. 3 is an example of a block diagram of the pixel control circuit 102 included in the photoelectric conversion apparatus according to the present embodiment.

As illustrated in FIG. 3, the pixel control circuit 102 has a pixel row selection circuit 120 and a pixel output circuit 121. Additionally, the pixel output circuit 121 includes multiple sets of a first pixel buffer circuit 122, a second pixel buffer circuit 123, and a third pixel buffer circuit 124. The pixel control circuit 102 receives control signals PRES, PTX, and PSEL from the timing control circuit 305. Additionally, the pixel row selection circuit 120 receives an address signal ADDP from the timing control circuit 305. The pixel row selection circuit 120 inputs a row selection signal to the pixel output circuit 121 based on the address signal ADDP. The first pixel buffer circuit 122, the second pixel buffer circuit 123, and the third pixel buffer circuit 124 supply the control signals PRES, PTX, and PSEL, respectively, to the pixels 110 disposed in the row selected by the row selection signal via the control line 103. The pixel control circuit 102 is supplied with the voltage SVDD and the voltage SGND, which respectively serve as a high-level voltage and a low-level voltage in the control signal output by the pixel output circuit 121. Note that, when the control signal is at a high level, the corresponding transistors are turned on, and when the control signal is at a low level, the corresponding transistors are turned off. Note that the low-level voltage is not limited to the voltage SGND, and a negative voltage may be supplied. For example, the control signal PTX supplied to the gate of a transfer transistor may have a high level at the voltage SVDD and a low level at a voltage VTXL (VTXL<GND). In this case, the transfer transistor can be turned off more reliably.

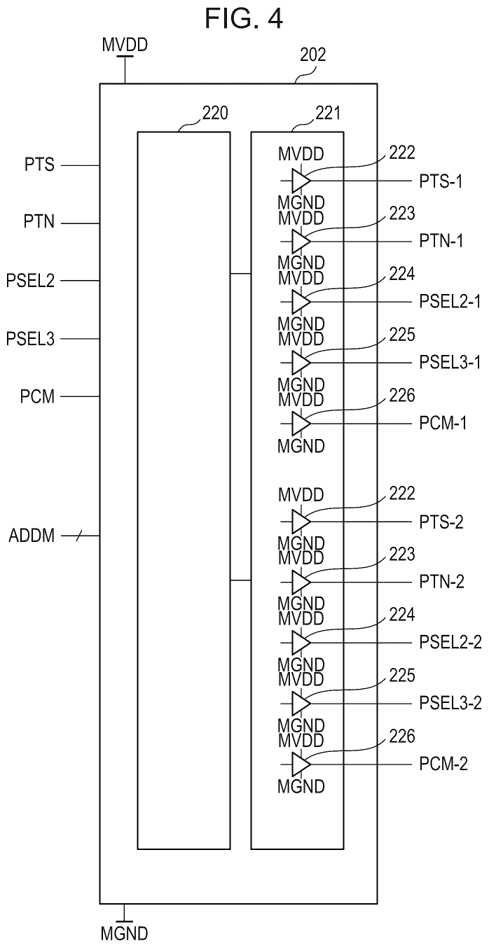

FIG. 4 is an example of a block diagram of the memory control circuit 202 included in the photoelectric conversion apparatus according to the present embodiment.

As illustrated in FIG. 4, the memory control circuit 202 has a memory row selection circuit 220 and a memory output circuit 221. Additionally, the memory output circuit 221 includes multiple sets of a first memory buffer circuit 222, a second memory buffer circuit 223, a third memory buffer circuit 224, a fourth memory buffer circuit 225, and a fifth memory buffer circuit 226. The memory control circuit 202 receives control signals PTS, PTN, PSEL2, PSEL3, and PCM from the timing control circuit 305. Additionally, the memory row selection circuit 220 receives an address signal ADDM from the timing control circuit 305. The memory row selection circuit 220 inputs a row selection signal to the memory output circuit 221 based on the address signal ADDM. The first memory buffer circuit 222 and the second memory buffer circuit 223 supply the control signals PTS and PTN, respectively, to the memory circuits 210 disposed in the row selected by the row selection signal via the control line 203. Additionally, the third memory buffer circuit 224, the fourth memory buffer circuit 225, and the fifth memory buffer circuit 226 supply the control signals PSEL2, PSEL3, and PCM, respectively, to the memory circuits 210 disposed in the row selected by the row selection signal via the control line 203. The memory control circuit 202 is supplied with the voltage MVDD and the voltage MGND, which respectively serve as a high-level voltage and a low-level voltage in the control signal output by the memory output circuit 221. Note that, when the control signal is at a high level, the corresponding transistors are turned on, and when the control signal is at a low level, the corresponding transistors are turned off.

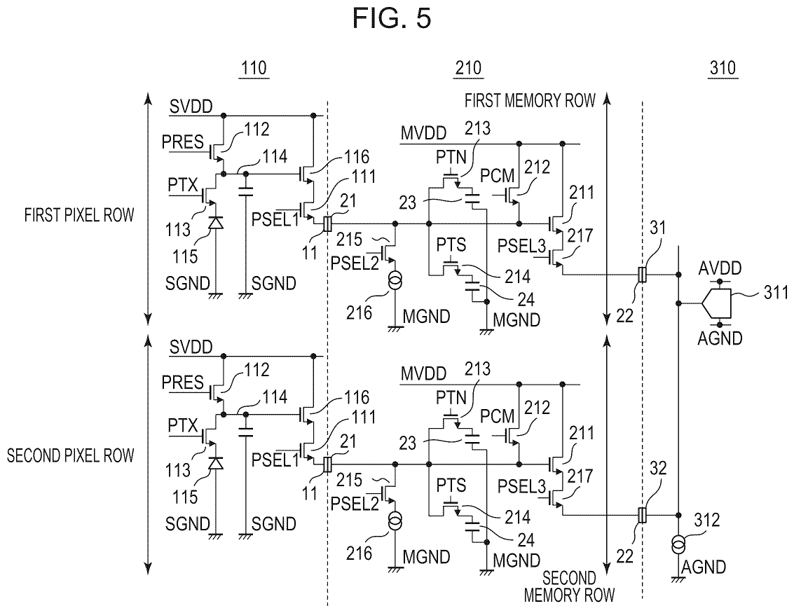

FIG. 5 is an example of a circuit diagram of the pixels 110, the memory circuits 210, and the column circuit 310 included in the photoelectric conversion apparatus according to the present embodiment. FIG. 5 illustrates two rows of pixels 110 disposed in the same column (a first pixel located in a first pixel row and a second pixel located in a second pixel row) and two rows of memory circuits 210 (a first memory circuit located in a first memory row and a second memory circuit located in a second memory row). Note that, in this specification, the row where the pixels 110 are disposed may be referred to as a “pixel row,” and the row where the memory circuits 210 are disposed may be referred to as a “memory row.” Note that the present disclosure can be applied to both front-illuminated and back-illuminated sensors. Note that, in the first row and the second row, the same components are assigned the same number. The components disposed in the first row are primarily described, while the description of the components disposed in the second row may be omitted.

As illustrated in FIG. 5, each pixel 110 has a photoelectric conversion element 115, a transfer transistor 113, and a floating diffusion 114. Hereinafter, in this specification, the floating diffusion 114 may be referred to as the FD 114 (FD stands for Floating Diffusion). The FD 114 may also be described as the floating diffusion region 114. The pixel 110 further has a reset transistor 112 for resetting the FD 114, an amplification transistor 116 for amplifying the signal, and a selection transistor 111. Additionally, the photoelectric conversion element 115 is electrically connected to a voltage SGND node (reference voltage node), and is supplied with the reference voltage. Furthermore, the reset transistor 112 and the amplification transistor 116 are electrically connected to a voltage SVDD node (power supply voltage node), and are supplied with the power supply voltage.

Note that the transfer transistor 113, the reset transistor 112, the amplification transistor 116, and the selection transistor 111 may each be an N-type MOS transistor or a P-type MOS transistor. In the present embodiment, the case will be described where, of electron-positive hole pairs generated by the photoelectric conversion element 115 based on light incidence, electrons are used as signal charges. When electrons are used as signal charges, each transistor included in the pixel 110 may be configured as an N-type MOS transistor. However, signal charges are not limited to electrons, and positive holes may be used as signal charges. When positive holes are used as signal charges, each transistor included in the pixel 110 may be configured as a P-type MOS transistor, different from that described in the present embodiment.

The photoelectric conversion element 115 is, for example, a photodiode. The photoelectric conversion element 115 is not limited to a photodiode, and may be, for example, a photoelectric conversion film. The photoelectric conversion element 115 receives the light incident on the pixel 110, generates the signal charge in response to the incident light, and accumulates the signal charge. The reset transistor 112 is driven by the control signal PRES. When the reset transistor 112 is turned on, the FD 114 is reset to a voltage based on the power supply voltage. The reset of the FD 114 is then released when the reset transistor 112 is turned off. The transfer transistor 113 is driven by the control signal PTX. When the transfer transistor 113 is turned on, the signal charge generated by the photoelectric conversion element 115 is transferred to the FD 114. The FD 114 functions as a charge-to-voltage converter configured to temporarily retain the signal charge input from the photoelectric conversion element 115 and to convert the retained signal charge into a voltage signal. The amplification transistor 116 amplifies a pixel signal converted by the FD 114.

The selection transistor 111 is driven by the control signal PSEL1, connects the amplification transistor 116 to the memory circuit 210, and outputs the pixel signal amplified by the amplification transistor 116 to the memory circuit 210.

Note that the configuration of each pixel 110 illustrated in FIG. 5 is merely an example, and may further have transistors. For example, a transistor that changes the capacitance value of the FD 114 or a transistor that discharges the signal charge from the photoelectric conversion element 115 may be further provided. Alternatively, the configuration may be such that the selection and deselection states of each pixel 110 are changed by the voltage input from the reset transistor 112 to the FD 114, without having the selection transistor 111.

Each memory circuit 210 has an amplification transistor 211, a reset transistor 212, an N signal transistor 213, and an S signal transistor 214. The memory circuit 210 further has a pixel selection transistor 215, a current source 216, a memory selection transistor 217, an N signal memory circuit (first capacitive element) 23, and an S signal memory circuit (second capacitive element) 24. Here, the N signal is a reset-level signal of the pixel 110, and the S signal is a photoelectric conversion signal of the pixel 110. Each transistor operates based on a control signal supplied by the memory control circuit 202. The current source 216 supplies current to the amplification transistor 116. Additionally, the current source 216 and the amplification transistor 116 function as a source follower circuit and output a pixel signal.

Note that each transistor may be an N-type MOS transistor or a P-type MOS transistor. In the present embodiment, the case will be described where, of electron-positive hole pairs generated by the photoelectric conversion element 115 based on light incidence, electrons are used as signal charges. When electrons are used as signal charges, each transistor included in the memory circuit 210 may be configured as an N-type MOS transistor. However, signal charges are not limited to electrons, and positive holes may be used as signal charges. When positive holes are used as signal charges, each transistor included in the memory circuit 210 may be configured as a P-type MOS transistor, different from that described in the present embodiment.

The column circuit 310 has an AD conversion circuit 311 and a current source 312. In the present embodiment, multiple pixels 110 and memory circuits 210 disposed in two rows are configured to share one AD conversion circuit 311; alternatively, multiple pixels 110 and memory circuits 210 disposed in three or more rows may share one AD conversion circuit 311.

Note that the first substrate 100 and the second substrate 200 may be bonded together using hybrid bonding. Now, “hybrid bonding” mentioned here will be described. The first substrate 100 has a first metal part 11 and a first insulating film, and the second substrate 200 has a second metal part 21 and a second insulating film. Then, on the bonding surface between the first substrate 100 and the second substrate 200, the bonding portion of the first metal part 11 and the second metal part 21, and the bonding portion of the first insulating film and the second insulating film, are disposed. Note that the second substrate 200 and the third substrate 300 may likewise be bonded together by hybrid bonding. In other words, the second substrate 200 has a third metal part 22 and a third insulating film, and the third substrate 300 has a fourth metal part 31 and a fourth insulating film. Then, on the bonding surface between the second substrate 200 and the third substrate 300, the bonding portion of the third metal part 22 and the fourth metal part 31, and the bonding portion of the third insulating film and the fourth insulating film, are disposed. Note that, in a plan view with respect to the first substrate 100, the bonding portion of the first metal part 11 and the second metal part 21 may be disposed to overlap at least partially with the pixel array 101. Note that the bonding portion of the third metal part 22 and the fourth metal part 31 may be disposed to overlap at least partially with the pixel array 101.

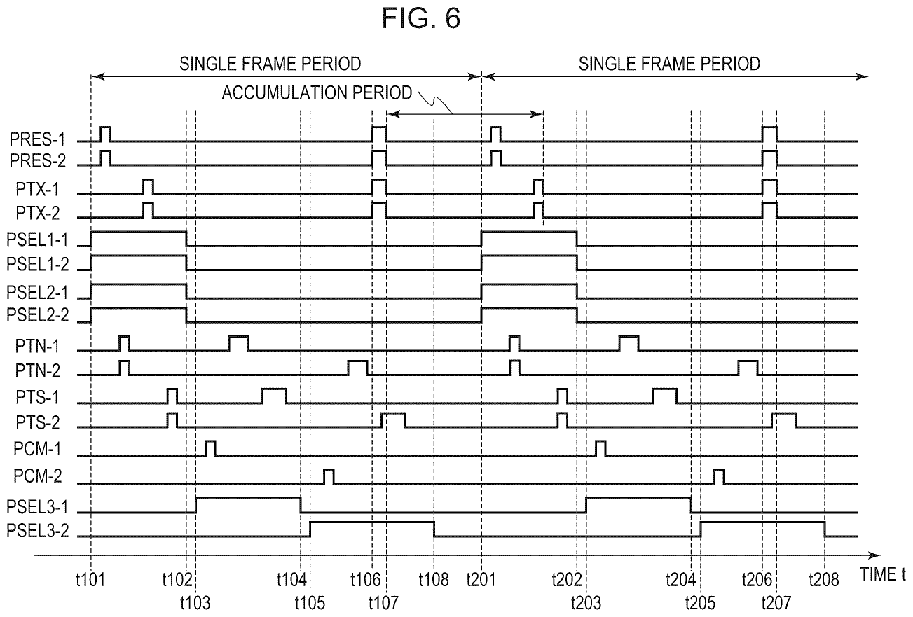

FIG. 6 is an example of a driving timing chart of the photoelectric conversion apparatus according to the present embodiment. FIG. 6 indicates time on the horizontal axis and voltage on the vertical axis, and schematically represents the timing of each driving pulse (each control signal). FIG. 6 also represents the timing when reading the pixel signals corresponding to the two rows of pixels 110 and the memory circuits 210 illustrated in FIG. 5. The present embodiment illustrates an all-row simultaneous operation, which is the so-called global shutter driving. In FIG. 6, driving of pixels 110 disposed in the third pixel row and beyond, such as pixels (third pixels) 110 disposed in the third pixel row and pixels (fourth pixels) 110 disposed in the fourth pixel row, is omitted. However, in the global shutter driving, the pixels 110 disposed in the third pixel row and beyond are driven in the same manner as the pixels 110 disposed in the first pixel row and the second pixel row illustrated in FIG. 6. Furthermore, in FIG. 6, driving of memory circuits 210 disposed in the third memory row and beyond, such as memory circuits (third memory circuits) 210 disposed in the third memory row and memory circuits (fourth memory circuits) 210 disposed in the fourth memory row, is omitted. However, in the global shutter driving, the memory circuits 210 disposed in the third memory row and beyond are driven in the same manner as the memory circuits 210 disposed in the first memory row and the second memory row illustrated in FIG. 6.

In FIG. 6, the period from time t101 to time t201 corresponds to one frame, and the period after t201 corresponds to the next frame. Note that the control signals illustrated in FIG. 6 correspond to the control signals illustrated in FIGS. 3, 4, and 5.

At time t101, control signals PSEL1-1 and PSEL1-2 change from a low level to a high level, and all rows with multiple pixels 110 disposed enter a selected state.

Note that the control signal PSEL1-1 indicates the control signal PSEL1 for the first row, and the control signal PSEL1-2 indicates the PSEL1 for the second row. Other control signals are also denoted in the same manner. Additionally, at time t101, control signals PSEL2-1 and PSEL2-2 change from a low level to a high level, and the amplification transistors 116 operate as a source follower circuit.

At time t102, the control signals PSEL1-1 and PSEL1-2 change from a high level to a low level, and the period in which all rows with multiple pixels 110 disposed are selected ends. During the period from time t101 to time t102, control signals PRES-1 and PRES-2 change from a low level to a high level, and then control signals PTN-1 and PTN-2 change from a low level to a high level. After that, during the period from time t101 to time t102, control signals PTX-1 and PTX-2 change from a low level to a high level, and then control signal PTS-1 and PTS-2 change from a low level to a high level.

When the control signals PRES-1 and PRES-2 change from a low level to a high level, the FDs 114 included in the pixels 110 disposed in all rows are reset.

After that, when the control signals PTN-1 and PTN-2 change from a low level to a high level, reset-level signals output from the FDs 114 are retained in the N signal memory circuits 23. After that, when the control signals PTX-1 and PTX-2 change from a low level to a high level, photoelectric conversion signals accumulated in the photoelectric conversion elements 115 are transferred to the FDs 114. After that, when the control signals PTS-1 and PTS-2 change from a low level to a high level, the photoelectric conversion signals are retained in the S signal memory circuits 24. With this driving operation, the write operation to the memory circuits 210 is completed at time t102.

At time t103, a control signal PSEL3-1 changes from a low level to a high level, and the read operation from the memory circuits 210 disposed in the first memory row starts. Additionally, at time t104, the control signal PSEL3-1 changes from a high level to a low level, and the read operation from the memory circuits 210 disposed in the first memory row ends.

During the period from time t103 to time t104, control signals PCM-1, PTN-1, and PTS-1 sequentially change from a low level to a high level. When the control signal PCM-1 changes from a low level to a high level, the gate of the amplification transistor 211 is reset. After that, when the control signal PTN-1 changes from a low level to a high level, the N signal retained in the N signal memory circuit 23 is read to the subsequent AD conversion circuit 311 and converted into a digital signal. Then, the N signal converted into a digital signal is retained in the column memory circuit 302. After that, when the control signal PTS-1 changes from a low level to a high level, the S signal retained in the S signal memory circuit 24 is read to the subsequent AD conversion circuit 311 and converted into a digital signal. Then, the S signal converted into a digital signal is retained in the column memory circuit 302. The horizontal scanning circuit 303 sequentially selects the column memory circuit 302 retaining the N signal and the S signal, and the N signal and the S signal are output to the outside of the photoelectric conversion apparatus 10 via the output circuit 306.

At time t105, a control signal PSEL3-2 changes from a low level to a high level, and the read operation from the memory circuits 210 disposed in the second memory row starts. Additionally, at time t108, the control signal PSEL3-2 changes from a high level to a low level, and the read operation from the memory circuits 210 disposed in the second memory row ends. During the period from time t105 to time t108, the read operation from the memory circuits 210 in the second memory row is performed by the same driving operation as that in the read operation from the memory circuits 210 in the first memory row, performed during the period from time t103 to time t104. Note that, after time t201, the operation during the period from time t101 to time t108 is repeated.

As described above, a first period, during which the pixels 110 in the first pixel row output analog signals to the memory circuits 210 in the first memory row, overlaps at least partially with a second period, during which the pixels 110 in the second pixel row output analog signals to the memory circuits 210 in the second memory row. Then, the memory circuits 210 disposed in the first memory row and the memory circuits 210 disposed in the second memory row sequentially output the analog signals to the AD conversion circuit 311. Additionally, a third period, during which the pixels 110 disposed in the third pixel row output analog signals to the memory circuits 210 disposed in the third memory row, overlaps at least partially with a fourth period, during which the pixels 110 disposed in the fourth pixel row output analog signals to the memory circuits 210 disposed in the fourth memory row. Then, the memory circuits 210 disposed in the third memory row and the memory circuits 210 disposed in the fourth memory row sequentially output the analog signals to the AD conversion circuit 311. Furthermore, the first period overlaps at least partially with the third period. This driving operation is the so-called global shutter driving. Typically, the start of each of the first period, the second period, the third period, and the fourth period is simultaneously controlled. Additionally, the end of each of the first period, the second period, the third period, and the fourth period is also simultaneously controlled. In other words, the start times of the first period, the second period, the third period, and the fourth period are approximately the same. Additionally, the end times of the first period, the second period, the third period, and the fourth period are approximately the same.

Note that, during the period from time t106 to time t107, the control signals PRES-1, PRES-2, PTX-1, and PTX-2 change to a high level. Then, the reset operation of the photoelectric conversion elements 115 is performed for all rows simultaneously. With this operation, the signal charge accumulated in the photoelectric conversion elements 115 is reset, and charge accumulation of the photoelectric conversion elements 115 starts. In FIG. 6, during the period from time t107 to when the control signals PTX-1 and PTX-2 change from a low level to a high level after time t107 until the reading of the pixel signals starts again, the photoelectric conversion elements 115 accumulate the signal charge. This operation from time t106 to time t107 is the so-called global shutter operation, which can be performed during the pixel signal reading period, as illustrated in FIG. 6. That is, the pixel output circuit 121, which supplies the control signals to the pixels 110, will be driven during the pixel signal reading period. In that case, due to the effects of through current and the like, the power supply voltage and reference voltage may fluctuate, which could affect the pixel signals during the reading period. For example, if the pixel signals corresponding to the first pixel row and the second pixel row are at the same level, the S signal of the second row is affected by the global shutter operation and deteriorates compared to the S signal of the first row. As a result, horizontal stripe noise may appear in the resulting image.

In the present embodiment, the configuration is such that the pixel control circuit 102 is disposed on the first substrate 100, which is a different substrate from the second substrate 200 on which the memory circuits 210 are disposed. According to this configuration, even if the power supply voltage and the reference voltage fluctuate during the global shutter operation, its impact on the signal reading operation of the memory circuits 210 can be reduced, thereby improving the image quality of the obtained image.

Note that the pixel array 101 and the pixel control circuit 102 may be electrically separated from the memory array 201 and the memory control circuit 202. For example, the voltage SVDD node, electrically connected to the pixel control circuit 102, and a voltage MVDD node, electrically connected to the memory control circuit 202, may be electrically separated. Additionally, for example, the voltage SGND node, electrically connected to the pixel control circuit 102, and a voltage MGND node, electrically connected to the memory control circuit 202, may be electrically separated. Furthermore, for example, the voltage SVDD node and the voltage SGND node, electrically connected to the pixel control circuit 102, and the voltage MVDD node and the voltage MGND node, electrically connected to the memory control circuit 202, may be electrically separated. Note that the pixel array 101 and the pixel control circuit 102 may be electrically separated from the signal processing circuit 301. For example, the voltage SVDD node, electrically connected to the pixel control circuit 102, and a voltage AVDD node, electrically connected to the signal processing circuit 301, may be electrically separated. Additionally, for example, the voltage SGND node, electrically connected to the pixel control circuit 102, and a voltage AGND node, electrically connected to the signal processing circuit 301, may be electrically separated. Furthermore, for example, the voltage SVDD node and the voltage SGND node, electrically connected to the pixel control circuit 102, and the voltage AVDD node and the voltage AGND node, electrically connected to the signal processing circuit 301, may be electrically separated. With the above-mentioned configuration, even if the power supply voltage and the reference voltage fluctuate during the global shutter operation, its impact on the signal reading operation of the memory circuits 210 can be reduced, thereby further improving the image quality of the obtained image.

Note that the global shutter operation in the present embodiment may drive all pixels 110 disposed in all rows simultaneously, or it may drive the pixels 110 disposed in multiple rows among all rows by dividing them into multiple blocks.

That is, the start and end of the accumulation period for multiple pixels 110 included in a single block are the same for each other. On the other hand, the start and end of the accumulation period are different between one block and another block. Such block-by-block partial global shutter operations are also possible. This driving operation is such that the first period and the third period mentioned above do not overlap. Note that how the blocks are divided can be changed as needed. For example, a single block may consist of multiple pixels 110 in all columns of one row. Alternatively, a single block may consist of multiple pixels 110 in multiple rows and columns, which form a portion of the pixel array 101.

Moreover, it is also possible to appropriately switch between the operation of driving all rows simultaneously and the operation of driving the blocks separately.

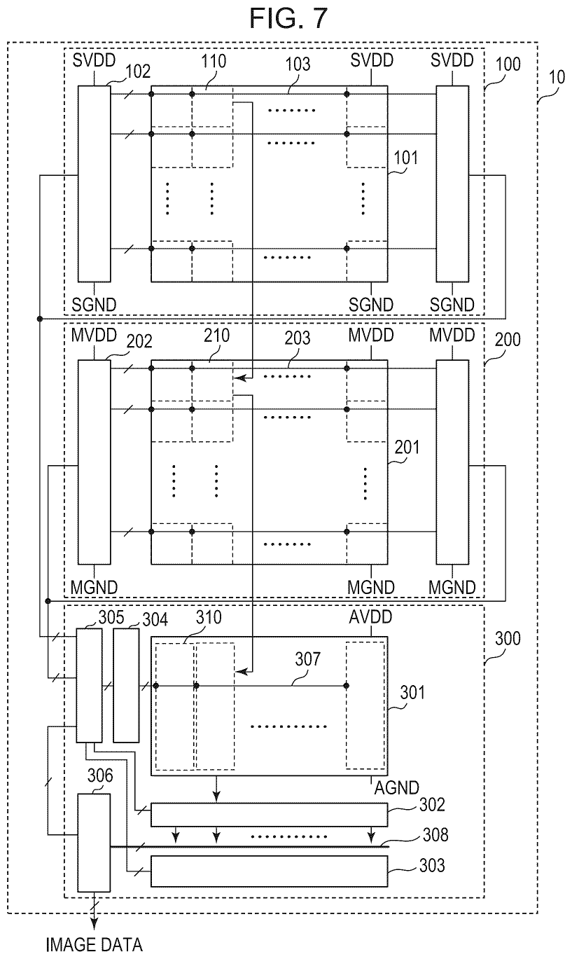

A photoelectric conversion apparatus according to a first modification of the first embodiment of the present disclosure will be described using FIG. 7. Note that components that are the same as those in the first embodiment are assigned the same reference numerals, and descriptions of these components may be omitted or simplified.

This modification of the first embodiment differs from the first embodiment in the configuration where multiple pixel control circuits 102 and multiple memory control circuits 202 are disposed. FIG. 7 is an example of a block diagram of the photoelectric conversion apparatus 10 according to this modification.

As illustrated in FIG. 7, the first substrate 100 has multiple pixel control circuits 102. Additionally, the second substrate 200 has multiple memory control circuits 202. As an example illustrated in FIG. 7, two pixel control circuits 102 are disposed on both sides of the pixel array 101, and two memory control circuits 202 are disposed on both sides of the memory array 201. With this configuration, by supplying control signals from both sides of the control lines 103 and 203, the pixels 110 and the memory circuits 210 can be controlled at higher speed.

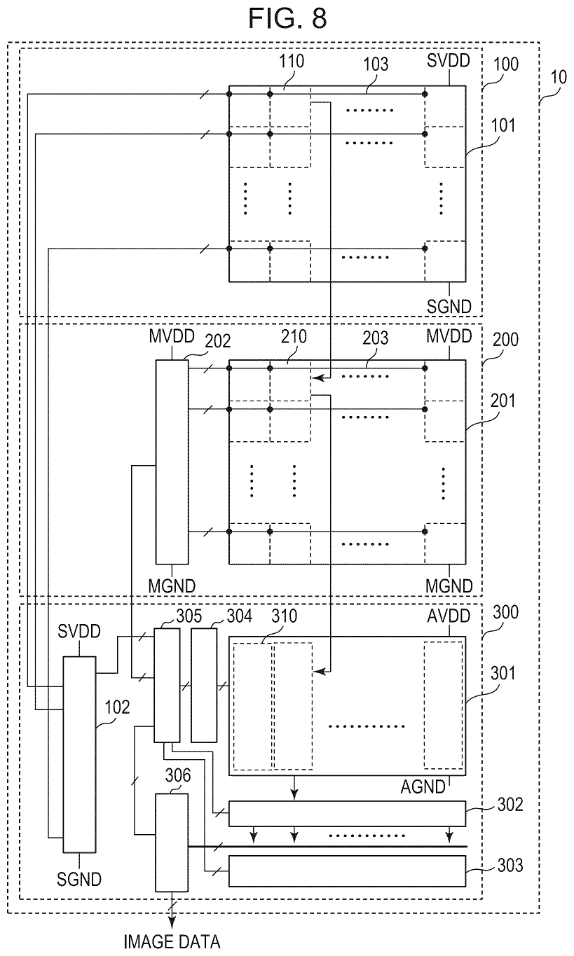

A photoelectric conversion apparatus according to a second modification of the first embodiment of the present disclosure will be described using FIG. 8. Note that components that are the same as those in the first embodiment are assigned the same reference numerals, and descriptions of these components may be omitted or simplified.

The second modification of the first embodiment differs from the first embodiment in the position where the pixel control circuit 102 is provided. FIG. 8 is an example of a block diagram of the photoelectric conversion apparatus 10 according to this modification.

As illustrated in FIG. 8, the third substrate 300 has the pixel control circuit 102. With this configuration, there is no need to provide the first substrate 100 with the pixel control circuit 102. Therefore, the components (such as the pixels 110) disposed on the first substrate 100 can be configured using N-type MOS transistors without using P-type MOS transistors. As a result, the process of forming the first substrate 100 is simplified, enabling cost reduction.

### Second Embodiment

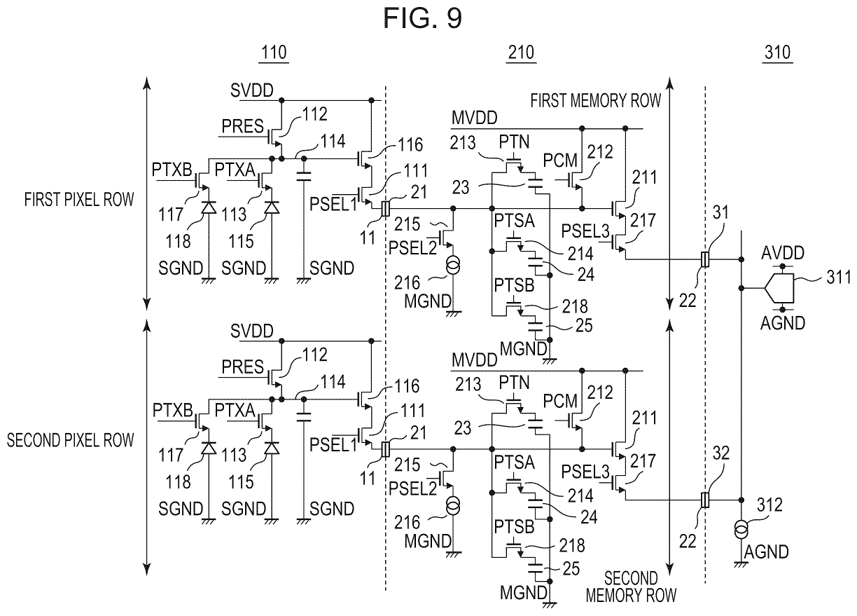

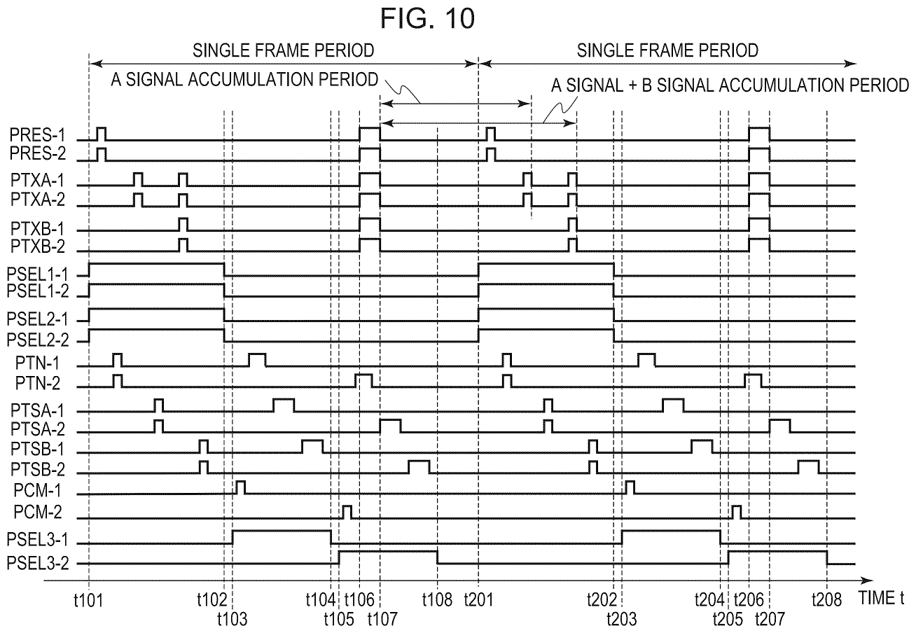

The photoelectric conversion apparatus 10 according to a second embodiment of the present disclosure will be described using FIGS. 9 and 10. Note that components that are the same as those in the first embodiment are assigned the same reference numerals, and descriptions of these components may be omitted or simplified.

The present embodiment differs from the first embodiment in the configuration in which each pixel 110 has multiple photoelectric conversion elements. FIG. 9 is an example of a circuit diagram of the pixels 110, the memory circuits 210, and the column circuit 310 included in the photoelectric conversion apparatus according to the present embodiment. FIG. 9 illustrates two rows of pixels 110 disposed in the same column (a first pixel located in a first pixel row and a second pixel located in a second pixel row) and two rows of memory circuits 210 (a first memory circuit located in a first memory row and a second memory circuit located in a second memory row). Note that the present disclosure can be applied to both front-illuminated and back-illuminated sensors. Note that, in the first row and the second row, the same components are assigned the same number. The components disposed in the first row are primarily described, while the description of the components disposed in the second row may be omitted.

As illustrated in FIG. 9, each pixel 110 has the photoelectric conversion element 115, a second photoelectric conversion element 118, the transfer transistor 113, a second transfer transistor 117, and the FD 114. Hereinafter, in this specification, the photoelectric conversion element 115 may be referred to as the first photoelectric conversion element 115, and the transfer transistor 113 may be referred to as the first transfer transistor 113. The pixel 110 further has the reset transistor 112 for resetting the FD 114, the amplification transistor 116 for amplifying the signal, and the selection transistor 111. Additionally, the first photoelectric conversion element 115 and the second photoelectric conversion element 118 are electrically connected to the voltage SGND node (reference voltage node), and are supplied with the reference voltage. Furthermore, the reset transistor 112 and the amplification transistor 116 are electrically connected to the voltage SVDD node (power supply voltage node), and are supplied with the power supply voltage.

Note that the first transfer transistor 113, the second transfer transistor 117, the reset transistor 112, the amplification transistor 116, and the selection transistor 111 may each be an N-type MOS transistor or a P-type MOS transistor. In the present embodiment, the case will be described where, of electron-positive hole pairs generated by the photoelectric conversion element 115 and the second photoelectric conversion element 118 based on light incidence, electrons are used as signal charges. When electrons are used as signal charges, each transistor included in the pixel 110 may be configured as an N-type MOS transistor. However, signal charges are not limited to electrons, and positive holes may be used as signal charges. When positive holes are used as signal charges, each transistor included in the pixel 110 may be configured as a P-type MOS transistor, different from that described in the present embodiment.

The first photoelectric conversion element 115 and the second photoelectric conversion element 118 are, for example, photodiodes. The first photoelectric conversion element 115 and the second photoelectric conversion element 118 are not limited to photodiodes, and may be, for example, photoelectric conversion films. The first photoelectric conversion element 115 and the second photoelectric conversion element 118 receive the light incident on the pixel 110, generate the signal charge in response to the incident light, and accumulate the signal charge. The reset transistor 112 is driven by the control signal PRES. When the reset transistor 112 is turned on, the FD 114 is reset to a voltage based on the power supply voltage. The reset of the FD 114 is then released when the reset transistor 112 is turned off. The first transfer transistor 113 is driven by a control signal PTXA. When the first transfer transistor 113 is turned on, the signal charge generated by the first photoelectric conversion element 115 is transferred to the FD 114. The second transfer transistor 117 is driven by a control signal PTXB. When the second transfer transistor 117 is turned on, the signal charge generated by the second photoelectric conversion element 118 is transferred to the FD 114. The FD 114 functions as a charge-to-voltage converter configured to temporarily retain the signal charge input from at least one of the first photoelectric conversion element 115 and the second photoelectric conversion element 118 and convert the retained signal charge into a voltage signal. The amplification transistor 116 amplifies a pixel signal converted by the FD 114. The selection transistor 111 is driven by the control signal PSEL1, connects the amplification transistor 116 to the memory circuit 210, and outputs the pixel signal amplified by the amplification transistor 116 to the memory circuit 210. Note that, hereinafter, in this specification, a photoelectric conversion signal output from the pixel 110 corresponding to a first charge (first signal charge) generated by the first photoelectric conversion element 115 may be referred to as A signal. Additionally, a photoelectric conversion signal output from the pixel 110 corresponding to a second charge (second signal charge) generated by the second photoelectric conversion element 118 may be referred to as B signal.

Note that the configuration of each pixel 110 illustrated in FIG. 9 is merely an example, and may further have transistors. For example, a transistor that changes the capacitance value of the FD 114 or a transistor that discharges the signal charge from at least one of the first photoelectric conversion element 115 and the second photoelectric conversion element 118 may be further provided. Alternatively, the configuration may be such that the selection and deselection states of each pixel 110 are changed by the voltage input from the reset transistor 112 to the FD 114, without having the selection transistor 111.

Each memory circuit 210 has the amplification transistor 211, the reset transistor 212, the N signal transistor 213, the S signal transistor 214, and a second S signal transistor 218. The memory circuit 210 further has the pixel selection transistor 215, the current source 216, the memory selection transistor 217, the N signal memory circuit 23, the S signal memory circuit 24, and a second S signal memory circuit 25. Hereinafter, in this specification, the S signal transistor 214 may be referred to as the first S signal transistor 214, and the S signal memory circuit 24 may be referred to as the first S signal memory circuit 24. Here, the N signal is a reset-level signal of the pixel 110, and the S signal is a photoelectric conversion signal of the pixel 110. Each transistor operates based on a control signal supplied by the memory control circuit 202.

Note that each transistor may be an N-type MOS transistor or a P-type MOS transistor. In the present embodiment, the case will be described where, of electron-positive hole pairs generated by the first photoelectric conversion element 115 and the second photoelectric conversion element 118 based on light incidence, electrons are used as signal charges. When electrons are used as signal charges, each transistor included in the memory circuit 210 may be configured as an N-type MOS transistor. However, signal charges are not limited to electrons, and positive holes may be used as signal charges. When positive holes are used as signal charges, each transistor included in the memory circuit 210 may be configured as a P-type MOS transistor, different from that described in the present embodiment.

FIG. 10 is an example of a driving timing chart of the photoelectric conversion apparatus according to the present embodiment. FIG. 10 indicates time on the horizontal axis and voltage on the vertical axis, and schematically represents the timing of each driving pulse (each control signal). FIG. 10 also represents the timing when reading the pixel signals corresponding to the two rows of pixels 110 and the memory circuits 210 illustrated in FIG. 9. The present embodiment illustrates an all-row simultaneous operation, which is the so-called global shutter driving. In FIG. 10, driving of pixels 110 disposed in the third pixel row and beyond, such as pixels (third pixels) 110 disposed in the third pixel row and pixels (fourth pixels) 110 disposed in the fourth pixel row, is omitted. However, in the global shutter driving, the pixels 110 disposed in the third pixel row and beyond are driven in the same manner as the pixels 110 disposed in the first pixel row and the second pixel row illustrated in FIG. 10. Furthermore, in FIG. 10, driving of memory circuits 210 disposed in the third memory row and beyond, such as memory circuits (third memory circuits) 210 disposed in the third memory row and memory circuits (fourth memory circuits) 210 disposed in the fourth memory row, is omitted. However, in the global shutter driving, the memory circuits 210 disposed in the third memory row and beyond are driven in the same manner as the memory circuits 210 disposed in the first memory row and the second memory row illustrated in FIG. 10.

In FIG. 10, the period from time t101 to time t201 corresponds to one frame, and the period after t201 corresponds to the next frame. Note that the control signals illustrated in FIG. 10 correspond to the control signals illustrated in FIGS. 3, 4, and 9.

At time t101, control signals PSEL1-1 and PSEL1-2 change from a low level to a high level, and all rows with multiple pixels 110 disposed enter a selected state.

Note that the control signal PSEL1-1 indicates the control signal PSEL1 for the first row, and the control signal PSEL1-2 indicates PSEL1 for the second row. Other control signals are also denoted in the same manner. Additionally, at time t101, control signals PSEL2-1 and PSEL2-2 change from a low level to a high level, and the amplification transistors 116 operate as a source follower circuit.

At time t102, the control signals PSEL1-1 and PSEL1-2 change from a high level to a low level, and the period in which all rows with multiple pixels 110 disposed are selected ends. During the period from time t101 to time t102, control signals PRES-1 and PRES-2 change from a low level to a high level, and then control signals PTN-1 and PTN-2 change from a low level to a high level. After that, during the period from time t101 to time t102, control signals PTXA-1 and PTXA-2 change from a low level to a high level, and then control signals PTSA-1 and PTSA-2 change from a low level to a high level. After that, during the period from time t101 to time t102, control signals PTXA-1, PTXA-2, PTXB-1, and PTXB-2 change from a low level to a high level. After that, during the period from time t101 to time t102, control signals PTSB-1 and PTSB-2 change from a low level to a high level.

When the control signals PRES-1 and PRES-2 change from a low level to a high level, the FDs 114 included in the pixels 110 disposed in all rows are reset.

After that, when the control signals PTN-1 and PTN-2 change from a low level to a high level, reset-level signals output from the FDs 114 are retained in the N signal memory circuits 23. After that, when the control signals PTXA-1 and PTXA-2 change from a low level to a high level, photoelectric conversion signals accumulated in the first photoelectric conversion elements 115 are transferred to the FDs 114. After that, when the control signals PTSA-1 and PTSA-2 change from a low level to a high level, A signals output from the pixels 110 disposed in all rows are retained in the first S signal memory circuits 24. After that, when the control signals PTXA-1, PTXA-2, PTXB-1, and PTXB-2 change from a low level to a high level, A signals and B signals output from the pixels 110 disposed in all rows are transferred to the FDs 114. That is, each FD 114 retains a signal that is the sum of the A signal and the B signal. After that, when the control signals PTSB-1 and PTSB-2 change from a low level to a high level, the sums of the A signals and the B signals are retained in the second S signal memory circuits 25. With this driving operation, the write operation to the memory circuits 210 is completed at time t102.

At time t103, a control signal PSEL3-1 changes from a low level to a high level, and the read operation from the memory circuits 210 disposed in the first memory row starts. Additionally, at time t104, the control signal PSEL3-1 changes from a high level to a low level, and the read operation from the memory circuits 210 disposed in the first memory row ends.

During the period from time t103 to time t104, control signals PCM-1, PTN-1, PTSA-1, and PTSB-1 sequentially change from a low level to a high level. When the control signal PCM-1 changes from a low level to a high level, the gate of the amplification transistor 211 is reset. After that, when the control signal PTN-1 changes from a low level to a high level, the N signal retained in the N signal memory circuit 23 is read to the subsequent AD conversion circuit 311 and converted into a digital signal. Then, the N signal converted into a digital signal is retained in the column memory circuit 302. After that, when the control signal PTSA-1 changes from a low level to a high level, the A signal retained in the first S signal memory circuit 24 is read to the subsequent AD conversion circuit 311 and converted into a digital signal. Then, the A signal converted into a digital signal is retained in the column memory circuit 302. After that, when the control signal PTSB-1 changes from a low level to a high level, the sum of the A signal and the B signal retained in the second S signal memory circuit 25 is read to the subsequent AD conversion circuit 311 and converted into a digital signal. Then, the sum of the A signal and the B signal converted into a digital signal is retained in the column memory circuit 302. The horizontal scanning circuit 303 sequentially selects the column memory circuit 302 retaining the N signal, the A signal, and the sum of the A signal and the B signal, respectively, and the N signal, the A signal, and the sum of the A signal and the B signal are output to the outside of the photoelectric conversion apparatus 10 via the output circuit 306. Furthermore, in signal processing performed subsequently, the B signal is obtained by subtracting the A signal from the sum of the A signal and the B signal. Then, by comparing the A signal and the B signal, focus detection is performed through phase difference detection.

At time t105, a control signal PSEL3-2 changes from a low level to a high level, and the read operation from the memory circuits 210 disposed in the second memory row starts. Additionally, at time t108, the control signal PSEL3-2 changes from a high level to a low level, and the read operation from the memory circuits 210 disposed in the second memory row ends. During the period from time t105 to time t108, the read operation from the memory circuits 210 in the second memory row is performed by the same driving operation as that in the read operation from the memory circuits 210 in the first memory row, performed during the period from time t103 to time t104. Note that, after time t201, the operation during the period from time t101 to time t108 is repeated.

As described above, a first period, during which the pixels 110 in the first pixel row output analog signals to the memory circuits 210 in the first memory row, overlaps at least partially with a second period, during which the pixels 110 in the second pixel row output analog signals to the memory circuits 210 in the second memory row. Then, the memory circuits 210 disposed in the first memory row and the memory circuits 210 disposed in the second memory row sequentially output the analog signals to the AD conversion circuit 311. Additionally, a third period, during which the pixels 110 disposed in the third pixel row output analog signals to the memory circuits 210 disposed in the third memory row, overlaps at least partially with a fourth period, during which the pixels 110 disposed in the fourth pixel row output analog signals to the memory circuits 210 disposed in the fourth memory row. Then, the memory circuits 210 disposed in the third memory row and the memory circuits 210 disposed in the fourth memory row sequentially output the analog signals to the AD conversion circuit 311. Furthermore, the first period overlaps at least partially with the third period. This driving operation is the so-called global shutter driving. Typically, the start of each of the first period, the second period, the third period, and the fourth period is simultaneously controlled. Additionally, the end of each of the first period, the second period, the third period, and the fourth period is also simultaneously controlled. In other words, the start times of the first period, the second period, the third period, and the fourth period are approximately the same. Additionally, the end times of the first period, the second period, the third period, and the fourth period are approximately the same.

In the present embodiment, the configuration is such that the pixel control circuit 102 is disposed on the first substrate 100, which is a different substrate from the second substrate 200 on which the memory circuits 210 are disposed. According to this configuration, even if the power supply voltage and the reference voltage fluctuate during the global shutter operation, its impact on the signal reading operation of the memory circuits 210 can be reduced, thereby suppressing the image quality deterioration.

Furthermore, in the present embodiment, the configuration is such that each pixel 110 has the first photoelectric conversion element 115 and the second photoelectric conversion element 118, and focus detection can be performed through phase difference detection.

Note that, although the present embodiment describes an example of performing focus detection with a global shutter operation, it is also possible to control the pixels 110 disposed in each row to sequentially transfer the A signal and the B signal to the memory circuits 210. In other words, the signal transfer from the pixels 110 to the memory circuits 210 may be performed with a rolling shutter operation. Since the rolling shutter operation only requires control signals corresponding to, among all rows, multiple rows that are transferred simultaneously to be at a high level, it can reduce the current flowing over a short period compared to the global shutter operation.

Note that, if focus detection is not required, the first transfer transistor 113 and the second transfer transistor 117 can be driven with the same timing, and a global shutter operation that reads only the sum of the A signal and the B signal without reading the A signal can also be performed. Furthermore, if focus detection is not required, a rolling shutter operation that reads only the sum of the A signal and the B signal without reading the A signal can be performed, thereby reducing the current flowing over a short period.

Note that the pixel array 101 and the pixel control circuit 102 may be electrically separated from the memory array 201 and the memory control circuit 202. For example, the voltage SVDD node, electrically connected to the pixel control circuit 102, and the voltage MVDD node, electrically connected to the memory control circuit 202, may be electrically separated. Additionally, for example, the voltage SGND node, electrically connected to the pixel control circuit 102, and the voltage MGND node, electrically connected to the memory control circuit 202, may be electrically separated. Furthermore, for example, the voltage SVDD node and the voltage SGND node, electrically connected to the pixel control circuit 102, and the voltage MVDD node and the voltage MGND node, electrically connected to the memory control circuit 202, may be electrically separated. Note that the pixel array 101 and the pixel control circuit 102 may be electrically separated from the signal processing circuit 301. For example, the voltage SVDD node, electrically connected to the pixel control circuit 102, and the voltage AVDD node, electrically connected to the signal processing circuit 301, may be electrically separated. Additionally, for example, the voltage SGND node, electrically connected to the pixel control circuit 102, and the voltage AGND node, electrically connected to the signal processing circuit 301, may be electrically separated. Furthermore, for example, the voltage SVDD node and the voltage SGND node, electrically connected to the pixel control circuit 102, and the voltage AVDD node and the voltage AGND node, electrically connected to the signal processing circuit 301, may be electrically separated. With the above-mentioned configuration, even if the power supply voltage and the reference voltage fluctuate during the global shutter operation, its impact on the signal reading operation of the memory circuits 210 can be reduced, thereby more effectively suppressing the image quality deterioration.

Note that the global shutter operation in the present embodiment may drive all pixels 110 disposed in all rows simultaneously, or it may drive the pixels 110 disposed in multiple rows among all rows by dividing them into multiple blocks.

That is, the start and end of the accumulation period for multiple pixels 110 included in a single block are the same for each other. On the other hand, the start and end of the accumulation period are different between one block and another block. Such block-by-block partial global shutter operations are also possible. This driving operation is such that the first period and the third period mentioned above do not overlap. Note that how the blocks are divided can be changed as needed. For example, a single block may consist of multiple pixels 110 in all columns of one row. Alternatively, a single block may consist of multiple pixels 110 in multiple rows and columns, which form a portion of the pixel array 101.

Moreover, it is also possible to appropriately switch between the operation of driving all rows simultaneously and the operation of driving the blocks separately.

### Third Embodiment

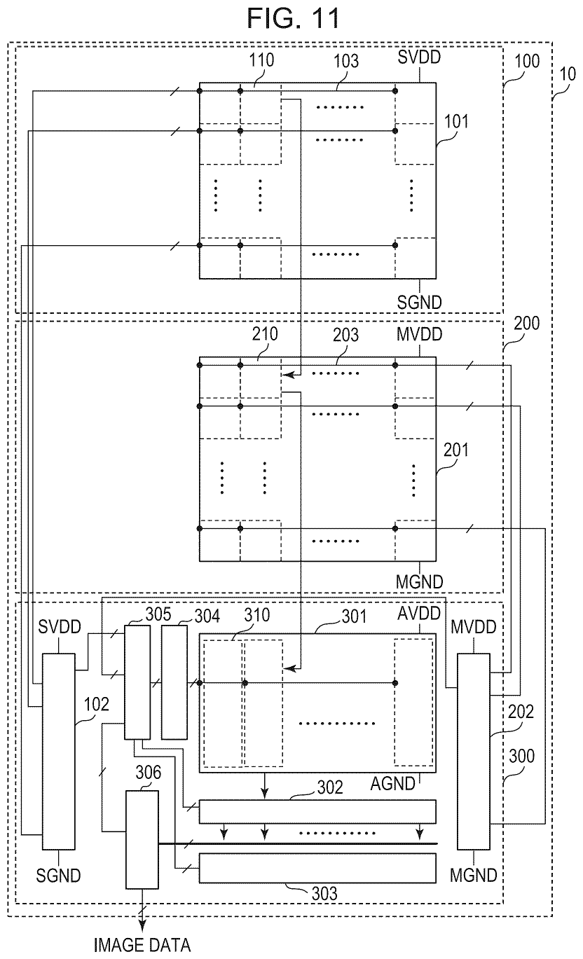

The photoelectric conversion apparatus 10 according to a third embodiment of the present disclosure will be described using FIG. 11. Note that components that are the same as those in the first and second embodiments are assigned the same reference numerals, and descriptions of these components may be omitted or simplified.

The present embodiment differs from the first and second embodiments in the position where the memory control circuit 202 is provided. FIG. 11 is an example of a block diagram of the photoelectric conversion apparatus 10 according to the present embodiment.

As illustrated in FIG. 11, the third substrate 300 has the pixel control circuit 102 and the memory control circuit 202. Additionally, the pixel array 101 and the pixel control circuit 102 are electrically separated from the memory array 201 and the memory control circuit 202. For example, the voltage SVDD node, electrically connected to the pixel control circuit 102, and the voltage MVDD node, electrically connected to the memory control circuit 202, may be electrically separated. Additionally, for example, the voltage SGND node, electrically connected to the pixel control circuit 102, and the voltage MGND node, electrically connected to the memory control circuit 202, may be electrically separated. Furthermore, for example, the voltage SVDD node and the voltage SGND node, electrically connected to the pixel control circuit 102, and the voltage MVDD node and the voltage MGND node, electrically connected to the memory control circuit 202, are electrically separated. According to this configuration, even if the power supply voltage and the reference voltage fluctuate during the global shutter operation, its impact on the signal reading operation of the memory circuits 210 can be reduced, thereby improving the image quality of the obtained image.

Note that the pixel array 101 and the pixel control circuit 102 may be electrically separated from the signal processing circuit 301. For example, the voltage SVDD node, electrically connected to the pixel control circuit 102, and the voltage AVDD node, electrically connected to the signal processing circuit 301, may be electrically separated. Additionally, for example, the voltage SGND node, electrically connected to the pixel control circuit 102, and the voltage AGND node, electrically connected to the signal processing circuit 301, may be electrically separated. Furthermore, for example, the voltage SVDD node and the voltage SGND node, electrically connected to the pixel control circuit 102, and the voltage AVDD node and the voltage AGND node, electrically connected to the signal processing circuit 301, may be electrically separated. With the above-mentioned configuration, even if the power supply voltage and the reference voltage fluctuate during the global shutter operation, its impact on the signal reading operation of the memory circuits 210 can be reduced, thereby further improving the image quality of the obtained image.

Furthermore, in the present embodiment, there is no need to provide the first substrate 100 with the pixel control circuit 102. Therefore, the components (such as the pixels 110) disposed on the first substrate 100 can be configured using N-type MOS transistors without using P-type MOS transistors. As a result, the process of forming the first substrate 100 is simplified, enabling cost reduction.

Note that the global shutter operation in the present embodiment may drive all pixels 110 disposed in all rows simultaneously, or it may drive the pixels 110 disposed in multiple rows among all rows by dividing them into multiple blocks.

That is, the start and end of the accumulation period for multiple pixels 110 included in a single block are the same for each other. On the other hand, the start and end of the accumulation period are different between one block and another block. Such block-by-block partial global shutter operations are also possible. This driving operation is such that the first period and the third period mentioned above do not overlap. Note that how the blocks are divided can be changed as needed. For example, a single block may consist of multiple pixels 110 in all columns of one row. Alternatively, a single block may consist of multiple pixels 110 in multiple rows and columns, which form a portion of the pixel array 101.

Moreover, it is also possible to appropriately switch between the operation of driving all rows simultaneously and the operation of driving the blocks separately.

### Fourth Embodiment

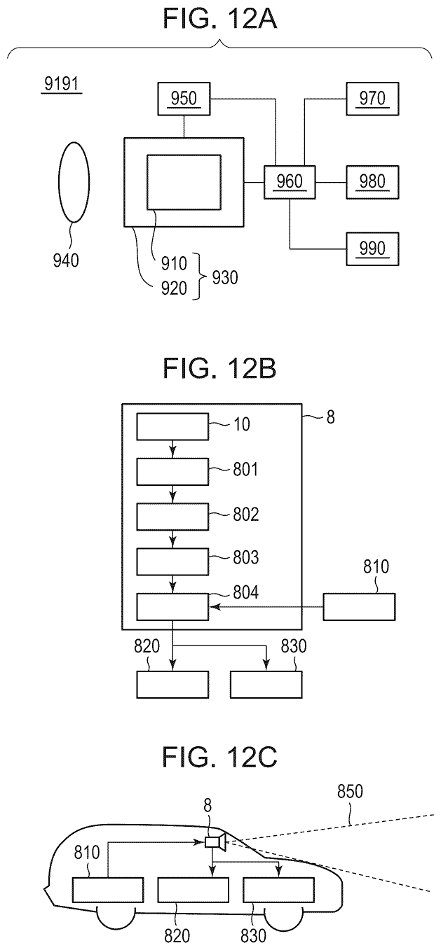

A fourth embodiment is applicable to any of the first to third embodiments. FIG. 12A is a schematic diagram illustrating equipment 9191 with a semiconductor apparatus 930 of the present embodiment. The photoelectric conversion apparatus of each of the above-described embodiments can be used for the semiconductor apparatus 930. The equipment 9191 including the semiconductor apparatus 930 will be described in detail. The semiconductor apparatus 930 may include a semiconductor device 910. The semiconductor apparatus 930 may, in addition to the semiconductor device 910, include a package 920 that houses the semiconductor device 910. The package 920 may include a base to which the semiconductor device 910 is fixed, and a cover, such as glass, that faces the semiconductor device 910. The package 920 may further include a bonding member, such as a bonding wire or bump, that connects a terminal provided on the base with a terminal provided on the semiconductor device 910.

The equipment 9191 may include at least any of an optical device 940, a control device 950, a processing device 960, a display device 970, a storage device 980, and a mechanical device 990. The optical device 940 corresponds to the semiconductor apparatus 930. The optical device 940 is equipped with an optical system, including a lens, shutter, or mirror, for example, that directs light to the semiconductor apparatus 930. The control device 950 controls the semiconductor apparatus 930. The control device 950 is a semiconductor device, such as an application-specific integrated circuit (ASIC), for example.

The processing device 960 processes signals output from the semiconductor apparatus 930. The processing device 960 is a semiconductor device, such as a central processing unit (CPU) or ASIC, for configuring an analog front-end (AFE) or a digital front-end (DFE). The display device 970 is an electroluminescence (EL) display device or a liquid crystal display device that displays information (images) obtained by the semiconductor apparatus 930. The storage device 980 is a magnetic device or semiconductor device that stores information (images) obtained by the semiconductor apparatus 930. The storage device 980 is volatile memory, such as SRAM or DRAM, or non-volatile memory, such as flash memory or hard disk drives.

The mechanical device 990 has a moving part or a propulsion part, such as a motor or an engine. In the equipment 9191, signals output from the semiconductor apparatus 930 are displayed on the display device 970 or transmitted externally by a communication device (not illustrated) included in the equipment 9191. For this purpose, it is preferable for the equipment 9191 to further include the storage device 980 and the processing device 960, in addition to the memory circuits and arithmetic circuits included in the semiconductor apparatus 930. The mechanical device 990 may be controlled based on signals output from the semiconductor apparatus 930.

Additionally, the equipment 9191 is suitable for electronic equipment such as information terminals with imaging functions (e.g., smartphones or wearable devices) and cameras (e.g., interchangeable lens cameras, compact cameras, video cameras, or surveillance cameras). The mechanical device 990 in the camera is capable of driving components of the optical device 940 for zooming, focusing, and shuttering operations. Alternatively, the mechanical device 990 in the camera is capable of moving the semiconductor apparatus 930 for anti-vibration operation.

Additionally, the equipment 9191 may be transportation equipment such as a vehicle, vessel, or aircraft (e.g., drones or airplanes). The mechanical device 990 in the transportation equipment may be used as a mobility device. The equipment 9191 as transportation equipment is particularly suitable for those that transport the semiconductor apparatus 930, or those that assist in and/or automate operation (control) through imaging functions. The processing device 960 for assisting and/or automating operation (control) can perform processing to operate the mechanical device 990 as a mobility device based on the information obtained by the semiconductor apparatus 930. Alternatively, the equipment 9191 may be medical equipment like endoscopes, measuring equipment like distance measuring sensors, analytical equipment like electron microscopes, office equipment like copiers, or industrial equipment like robots.

According to the above-described embodiments, favorable pixel characteristics can be achieved. Therefore, the value of the semiconductor apparatus can be enhanced. Here, enhancing value refers to at least one of the following: adding functions, improving performance, enhancing characteristics, increasing reliability, improving manufacturing yield, reducing environmental impact, cost reduction, miniaturization, and weight reduction.

Therefore, if the semiconductor apparatus 930 according to the present embodiment is used in the equipment 9191, the value of the equipment can also be enhanced. For example, mounting the semiconductor apparatus 930 on transportation equipment enables excellent performance in capturing external images or measuring the external environment outside the transportation equipment. Therefore, when manufacturing and selling transportation equipment, deciding to mount the semiconductor apparatus according to the present embodiment on the transportation equipment is advantageous for enhancing the performance of the transportation equipment itself. In particular, the semiconductor apparatus 930 is suitable for transportation equipment that performs driving assistance and/or autonomous driving using the information obtained by the semiconductor apparatus.

Additionally, a photoelectric conversion system and a moving entity of the present embodiment will be described using FIGS. 12B and 12C.

FIG. 12B illustrates an example of a photoelectric conversion system for a vehicle-mounted camera. A photoelectric conversion system 8 has the photoelectric conversion apparatus 10. The photoelectric conversion apparatus 10 is a photoelectric conversion apparatus (imaging apparatus) according to any of the above-described embodiments. The photoelectric conversion system 8 has an image processing unit 801 configured to perform image processing on multiple items of image data obtained by the photoelectric conversion apparatus 10 and a parallax obtaining unit 802 configured to calculate a parallax (phase difference between parallax images) from the multiple items of image data obtained by the photoelectric conversion system 8. Here, the photoelectric conversion system 8 may be equipped with an optical system (not illustrated), including a lens, shutter, or mirror, for example, that directs light to the photoelectric conversion apparatus 10. Additionally, each of the pixels included in the photoelectric conversion apparatus 10 may be provided with multiple photoelectric conversion units that are approximately conjugate to the pupil of the optical system. For example, multiple photoelectric conversion units that are approximately conjugate to the pupil are disposed corresponding to a single microlens. By receiving light beams that have passed through different positions of the pupil of the optical system, the multiple photoelectric conversion units enable the photoelectric conversion apparatus 10 to output image data corresponding to the light beams that have passed through the different positions. Then, the parallax obtaining unit 802 may calculate the parallax using the output image data. Additionally, the photoelectric conversion system 8 has a distance obtaining unit 803 configured to calculate a distance to an object based on the calculated parallax, and a collision determination unit 804 configured to determine whether there is a possibility of collision based on the calculated distance. Here, the parallax obtaining unit 802 and the distance obtaining unit 803 are examples of a distance information obtaining unit configured to obtain distance information to an object. In other words, distance information is information about parallax, defocus amount, distance to an object, and the like. The collision determination unit 804 may determine the possibility of collision using any of these items of distance information. Note that distance information may be obtained using time of flight (TOF). The distance information obtaining unit may be implemented by dedicatedly-designed hardware or by a software module. It may also be implemented by a field-programmable gate array (FPGA), an application-specific integrated circuit (ASIC), or a combination thereof.

The photoelectric conversion system 8 is connected to a vehicle information obtaining device 810 and can obtain vehicle information such as vehicle speed, yaw rate, steering angle, etc. Additionally, the photoelectric conversion system 8 is connected to a control electronic control unit (ECU) 820, which is a control device configured to output a control signal for generating a braking force for the vehicle, based on the determination result obtained by the collision determination unit 804. The photoelectric conversion system 8 is also connected to an alarm device 830 configured to issue a warning to the driver based on the determination result obtained by the collision determination unit 804. For example, if the collision determination unit 804 determines a high possibility of a collision as the determination result, the control ECU 820 performs vehicle control to avoid the collision and reduce damage, such as applying the brakes, releasing the accelerator, or limiting engine output. The alarm device 830 issues a warning to the user by sounding an alarm such as a beep, displaying alarm information on a screen of the car navigation system or the like, or providing vibrations through the seatbelt or steering wheel.

In the present embodiment, images of the surroundings of the vehicle, such as the front or rear, are captured by the photoelectric conversion system 8.

FIG. 12C illustrates the photoelectric conversion system 8 when capturing images of the front of the vehicle (imaging range 850). The vehicle information obtaining device 810 sends an instruction to the photoelectric conversion system 8 or the photoelectric conversion apparatus 10. With this configuration, the accuracy of distance measurement can be further improved.

Although an example of performing control to avoid a collision with another vehicle has been described above, the photoelectric conversion system 8 is also applicable to controlling autonomous driving, such as following another vehicle, or ensuring the vehicle not to drift out of its lane. Furthermore, the photoelectric conversion system 8 is not limited to vehicles such as automobiles, and is applicable to moving entities (mobility devices) such as vessels, aircrafts, or industrial robots. This moving entity includes one or both of a driving force generating unit configured to generate a driving force that is primarily utilized for the movement of the moving entity, and a rotating body that is primarily utilized for the movement of the moving entity. The driving force generating unit may be an engine, a motor, or the like. The rotating body may include tires, wheels, screws of vessels, propellers of aircrafts, and the like. Furthermore, the photoelectric conversion system 8 can be applied not only to moving entities but also to equipment that utilizes object recognition widely, such as Intelligent Transport System (ITS).

In this specification, expressions such as “A or B,” “at least one of A and B,” “at least one of A and/or B,” and “one or more of A and/or B” include all possible combinations of the listed items, unless explicitly defined otherwise. That is, the above expressions are understood to disclose all cases, including the cases where at least one A is included, at least one B is included, or at least one A and at least one B are both included. This also applies to combinations of three or more elements.

The above-described embodiments can be appropriately changed to the extent that they do not deviate from the technical idea. The disclosed content of this specification includes not only what is described in this specification but also all matters that can be understood from this specification and the drawings attached to this specification. Additionally, the disclosed content of this specification includes the complement set of the concepts described in this specification. That is, if this specification describes, for example, that “A is greater than B,” it can be said that the specification implicitly discloses that “A is not greater than B” even if the statement “A is not greater than B” is omitted. This is because, when stating “A is greater than B,” it is assumed that the case where “A is not greater than B” is taken into consideration.

According to embodiments of the present disclosure, it is possible to provide a photoelectric conversion apparatus with higher performance.

While the present disclosure includes exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-065498, filed Apr. 15, 2024, which is hereby incorporated by reference herein in its entirety.

What is claimed is:

1. A photoelectric conversion apparatus comprising:
a first substrate having a pixel array;
a second substrate having a memory array configured to retain an analog signal output by the pixel array; and
a third substrate having an analog-to-digital conversion circuit configured to convert the analog signal output by the memory array into a digital signal,
the second substrate having at least one memory control circuit configured to control the memory array, and
the first substrate or the third substrate having at least one pixel control circuit configured to control the pixel array.

2. A photoelectric conversion apparatus comprising:
a first substrate having a pixel array;
a second substrate having a memory array configured to retain an analog signal output by the pixel array;
a third substrate having an analog-to-digital conversion circuit configured to convert the analog signal output by the memory array into a digital signal;
at least one memory control circuit configured to control the memory array; and
at least one pixel control circuit configured to control the pixel array,
at least one of a power supply voltage node electrically connected to the pixel control circuit and a power supply voltage node electrically connected to the memory control circuit, or a reference voltage node electrically connected to the pixel control circuit and a reference voltage node electrically connected to the memory control circuit, being electrically separated.

3. The photoelectric conversion apparatus according to claim 1, wherein at least one of a power supply voltage node electrically connected to the pixel control circuit and a power supply voltage node electrically connected to the memory control circuit, or a reference voltage node electrically connected to the pixel control circuit and a reference voltage node electrically connected to the memory control circuit, is electrically separated.

4. The photoelectric conversion apparatus according to claim 1, wherein the pixel control circuit includes a pixel output circuit configured to output a control signal for controlling the pixel array, and the memory control circuit includes a memory output circuit configured to output a control signal for controlling the memory array.

5. The photoelectric conversion apparatus according to claim 1, wherein a pixel included in the pixel array has a photoelectric conversion element configured to generate charge in response to incident light, a floating diffusion configured to convert the charge into a signal, and an amplification transistor configured to amplify the signal, and the analog signal output by the pixel array is a signal output by the amplification transistor.

6. The photoelectric conversion apparatus according to claim 5, wherein the analog signal output by the pixel array is a signal output by a source follower circuit including a current source and the amplification transistor, the current source being configured to supply current to the amplification transistor.

7. The photoelectric conversion apparatus according to claim 1, wherein the pixel array has a plurality of pixels disposed in a plurality of rows and a plurality of columns, the memory array has a plurality of memory circuits disposed in a plurality of rows and a plurality of columns, and each of the plurality of memory circuits is configured to retain the analog signal output from a corresponding one of the plurality of pixels.

8. The photoelectric conversion apparatus according to claim 7, wherein the pixel control circuit controls at least one pixel among the plurality of pixels to output the analog signal to the memory array, and the memory control circuit controls at least one memory circuit among the plurality of memory circuits to output the analog signal to the analog-to-digital conversion circuit.

9. The photoelectric conversion apparatus according to claim 7, wherein:
the third substrate has a control circuit configured to control the pixel control circuit and the memory control circuit;
the plurality of pixels include a first pixel disposed in a first pixel row and a second pixel disposed in a second pixel row;
the plurality of memory circuits include a first memory circuit disposed in a first memory row and a second memory circuit disposed in a second memory row;
the control circuit controls the pixel control circuit such that, during a single frame, a first period during which the first pixel outputs the analog signal to the first memory circuit overlaps at least partially with a second period during which the second pixel outputs the analog signal to the second memory circuit; and
the control circuit controls the memory control circuit such that, during the single frame, the first memory circuit and the second memory circuit sequentially output the analog signal to the analog-to-digital conversion circuit.

10. The photoelectric conversion apparatus according to claim 9, wherein:
the plurality of pixels include a third pixel disposed in a third pixel row and a fourth pixel disposed in a fourth pixel row;
the plurality of memory circuits include a third memory circuit disposed in a third memory row and a fourth memory circuit disposed in a fourth memory row;
the control circuit controls the pixel control circuit such that, during the single frame, a third period during which the third pixel outputs the analog signal to the third memory circuit overlaps at least partially with a fourth period during which the fourth pixel outputs the analog signal to the fourth memory circuit;
the control circuit controls the memory control circuit such that, during the single frame, the first memory circuit, the second memory circuit, the third memory circuit, and the fourth memory circuit sequentially output the analog signal to the analog-to-digital conversion circuit; and
the first period overlaps at least partially with the third period.

11. The photoelectric conversion apparatus according to claim 9, wherein:
the plurality of pixels include a third pixel disposed in a third pixel row and a fourth pixel disposed in a fourth pixel row;
the plurality of memory circuits include a third memory circuit disposed in a third memory row and a fourth memory circuit disposed in a fourth memory row;
the control circuit controls the pixel control circuit and the memory control circuit such that, during the single frame, a third period during which the third pixel outputs the analog signal to the third memory circuit overlaps at least partially with a fourth period during which the fourth pixel outputs the analog signal to the fourth memory circuit;
the control circuit controls the memory control circuit such that, during the single frame, the first memory circuit, the second memory circuit, the third memory circuit, and the fourth memory circuit sequentially output the analog signal to the analog-to-digital conversion circuit; and
the first period does not overlap with the third period.

12. The photoelectric conversion apparatus according to claim 9, wherein:
the first pixel and the second pixel each have a photoelectric conversion element configured to generate charge in response to incident light and a transfer transistor configured to transfer the charge; and
the control circuit controls the pixel control circuit such that, during the single frame, a period in which the transfer transistor included in the first pixel is on during the first period overlaps at least partially with a period in which the transfer transistor included in the second pixel is on during the second period.

13. The photoelectric conversion apparatus according to claim 9, wherein:
the first pixel and the second pixel each have a first photoelectric conversion element configured to generate a first charge in response to incident light, a first transfer transistor configured to transfer the first charge, a second photoelectric conversion element configured to generate a second charge in response to incident light, and a second transfer transistor configured to transfer the second charge; and
the control circuit controls the pixel control circuit such that, during the single frame, a period in which the first transfer transistor and the second transfer transistor included in the first pixel are on during the first period overlaps at least partially with a period in which the first transfer transistor and the second transfer transistor included in the second pixel are on during the second period.

14. The photoelectric conversion apparatus according to claim 1, wherein a pixel included in the pixel array has a plurality of photoelectric conversion elements configured to generate charge in response to incident light, and the memory array retains the analog signal corresponding to a charge obtained by adding a plurality of charges respectively generated by the plurality of photoelectric conversion elements.

15. The photoelectric conversion apparatus according to claim 1, wherein the analog signal includes a reset-level signal and a photoelectric conversion signal, and a memory circuit included in the memory array has a first capacitive element configured to retain the reset-level signal and a second capacitive element configured to retain the photoelectric conversion signal.

16. The photoelectric conversion apparatus according to claim 1, wherein, in a plan view with respect to the first substrate, a bonding portion of the first substrate and the second substrate is disposed at a position overlapping at least partially with the pixel array.

17. The photoelectric conversion apparatus according to claim 1, wherein the first substrate has a first metal part and a first insulating film, and the second substrate has a second metal part and a second insulating film; and on a bonding surface between the first substrate and the second substrate, a bonding portion of the first metal part and the second metal part, and a bonding portion of the first insulating film and the second insulating film, are disposed.

18. The photoelectric conversion apparatus according to claim 1, wherein the second substrate has a plurality of the memory control circuits.

19. The photoelectric conversion apparatus according to claim 1, wherein the first substrate or the third substrate has a plurality of the pixel control circuits.

20. Equipment comprising:
the photoelectric conversion apparatus according to claim 1, the equipment further comprising at least one of:
an optical device configured to direct light to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus; or
a mechanical device configured to operate based on information obtained by the photoelectric conversion apparatus.
